(19) United States
(12) Patent Application Publication
(10) Pub. No.: US 2026/0334103 A1
(43) Pub. Date: Oct. 22, 2026

(54) Insulated Gate Bipolar Transistor Having Improved Electrical Performance

(71) Applicant: ThinSiC Inc., Santa Clara, CA (US)

(72) Inventors: Tirunelveli Subramaniam Ravi, San Jose, CA (US); Jinho Seo, Saratoga, CA (US); Bishnu Prasanna Gogoi, Scottsdale, AZ (US)

(73) Assignee: ThinSiC Inc., Santa Clara, CA (US)

(21) Appl. No.: 19/185,099

(22) Filed: Apr. 21, 2025

(51) Int. Cl. H01L 21/02; C30B 25/20; C30B 29/36; C30B 33/12; H10D 12/01

(52) U.S. Cl. CPC H10P 14/276; C30B 25/20; C30B 29/36; C30B 33/12; H10D 12/038; H10P 14/2904; H10P 14/3408

(57) ABSTRACT

Two or more IGBTs (insulated gate bipolar transistors) formed in or on a 4H silicon carbide (SiC) A-plane <1120> substrate of a first type. A merge layer is formed in the SiC substrate. The merge layer comprises an epitaxial layer of the first type formed by on-axis epitaxial lateral overgrowth. At least one epitaxial layer is formed overlying a surface of the merge layer. The at least one epitaxial layer is of a second type and at least 25 microns thick. The at least one epitaxial layer is formed by vertical epitaxial overgrowth. The at least one epitaxial layer is at least 25 microns thick and is a drift layer for the two or more IGBTs. An exfoliation process is configured to separate the SiC substrate at the merge layer from the two or more IGBTs. The SiC substrate is prepared and reused to form other semiconductor devices.

### FIELD

This invention relates to semiconductor device manufacture, and in particular to methods of forming an insulated gate bipolar transistor.

### BACKGROUND

The use of wide bandgap (WBG) semiconductors has increased dramatically in recent years in power electronics. Their ability to operate efficiently at higher voltages, powers, temperatures, and switching frequencies has enabled reduced cooling requirements, lower part counts, and the use of smaller passive components. WBG-based power electronics can further reduce the footprint and potentially the system cost of various renewable energy electrical equipment such as motor drivers and inverters.

Among the WBG semiconductors for power electronics, Silicon Carbide (SiC) has now been increasingly used for high voltage drivers (>1200V). From the substrate standpoint, 4H-Silicon carbide (SiC) Single Crystal Substrates have been used for both SiC and GaN devices since SiC and GaN epitaxial layers can be grown with reduced defects on SiC substrates. While the SiC substrate quality has dramatically improved in the recent years, the cost has not come down since substrate fabrication is a complex process starting with vapor phase ingot growth followed by ingot cropping, then wire sawing of individual wafers, and finally grinding and polishing of the substrate, and as of now, there has been no proven practical method to eliminate any of these foregoing steps.

As a semiconductor substrate for WBG semiconductors is being produced and devices that use high currents are fabricated, defects play a larger role and are magnified because die sizes are larger and any defect will contribute to more significant yield loss and potential lower reliability. Therefore, to maximize die yield, any cost reduction activity regarding the substrate and subsequent epitaxial layers formed on the substrate is paramount. Similarly, improving the electrical characteristics of the device formed on the substrate in conjunction with lowering fabrication costs will support integration into systems where they were not considered due to cost or performance. Furthermore, improving reliability of the device can be an essential component in utilizing a device where safety or critical operation is concerned. Improving device performance such as high frequency operation or increased voltage operation can also be a factor.

Accordingly, it is desirable to provide a system that lowers wafer processing costs while improving device performance to enable new uses for high power high efficiency semiconductor devices.

### BRIEF DESCRIPTION OF THE DRAWINGS

Various features of the system are set forth with particularity in the appended claims. The embodiments herein, can be understood by reference to the following description, taken in conjunction with the accompanying drawings, in which:

FIG. 1 is an illustration of a silicon carbide substrate (SiC) in accordance with an example embodiment;

FIG. 2 is an illustration of a p-type epitaxial layer overlying the silicon carbide substrate in accordance with an example embodiment;

FIG. 3 is an illustration of a p-type epitaxial layer formed overlying the silicon carbide substrate in accordance with an example embodiment;

FIG. 4 is an illustration of a hard mask layer overlying the epitaxial layer in accordance with an example embodiment;

FIG. 5 is an illustration of a plurality of openings formed in the hard mask layer in accordance with an example embodiment;

FIG. 6 is an illustration of a plurality of openings formed in the epitaxial layer in accordance with an example embodiment;

FIG. 7 is an illustration of a plurality of pillars formed in the epitaxial layer in accordance with an example embodiment;

FIG. 8 is an illustration of a refill layer formed over the plurality of pillars in accordance with an example embodiment;

FIG. 9 is an illustration of an exfoliation layer formed between the plurality of pillars in accordance with an example embodiment;

FIG. 10 is an illustration of a merge layer formed overlying the silicon carbide substrate in accordance with an example embodiment;

FIG. 11 is an illustration of an epitaxial layer overlying the merge layer in accordance with an example embodiment;

FIG. 12 in an illustration of a current spreading layer in the epitaxial layer in accordance with an example embodiment;

FIG. 13 is an illustration of a body implant layer in the epitaxial layer in accordance with an example embodiment;

FIG. 14 is an illustration of an opening formed in the epitaxial layer in accordance with an example embodiment;

FIG. 15 is an illustration of an implant layer formed on the bottom of a trench in accordance with an example embodiment;

FIG. 16 is an illustration of source regions formed in a body implant layer in accordance with an example embodiment;

FIG. 17 is an illustration of an implant layer formed adjacent to the source regions in accordance with an example embodiment;

FIG. 18 is an illustration of a gate oxide and a gate electrode formed in accordance with an example embodiment;

FIG. 19 is an illustration of a dielectric isolation layer with a plurality of contact openings in accordance with an example embodiment;

FIG. 20 is an illustration of a plurality of metal contacts formed in accordance with an example embodiment;

FIG. 21 is an illustration of a carrier wafer attached to an IGBT formed in the silicon carbide substrate in accordance with an example embodiment;

FIG. 22 is an illustration of a portion of silicon carbide substrate after an exfoliation process in accordance with an example embodiment;

FIG. 23 is an illustration of a back side metal deposited in accordance with an example embodiment;

FIG. 24 is an illustration of a silicon carbide substrate with an IGBT after being separated from the carrier wafer in accordance with an example embodiment;

FIG. 25A is an illustration of a silicon carbide substrate after exfoliation in accordance with an example embodiment;

FIG. 25B is an illustration of a reclaimed silicon carbide substrate in accordance with an example embodiment; and

FIG. 26 is an illustration showing a block diagram of the formation of an IGBT in accordance with an example embodiment.

### DETAILED DESCRIPTION

The following description of embodiment(s) is merely illustrative in nature and is in no way intended to limit the invention, its application, or uses.

For simplicity and clarity of the illustration(s), elements in the figures are not necessarily to scale, are only schematic, are non-limiting, and the same reference numbers in different figures denote the same elements, unless stated otherwise. Additionally, descriptions and details of well-known steps and elements are omitted for simplicity of the description. Notice that once an item is defined in one figure, it may not be discussed or further defined in the following figures.

The terms “first,” “second”, “third” and the like in the Claims or/and in the Detailed Description are used for distinguishing between similar elements and not necessarily for describing a sequence, either temporally, spatially, in ranking or in any other manner. It is to be understood that the terms so used are interchangeable under appropriate circumstances and that the embodiments described herein are capable of operation in other sequences than described or illustrated herein.

Processes, techniques, apparatus, and materials as known by one of ordinary skill in the art may not be discussed in detail but are intended to be part of the enabling description where appropriate.

While the specification concludes with claims defining the features of the invention that are regarded as novel, it is believed that the invention will be better understood from a consideration of the following description in conjunction with the drawing figures, in which like reference numerals are carried forward.

This invention is related to silicon carbide (SiC) epitaxy as a Wide Band Gap (WBG) material for the fabrication of semiconductor devices and its application for formation of semiconductor devices such as IGBT (Insulated Gate Bipolar Transistor). In general, one or more epitaxial layers are grown overlying a silicon carbide substrate. The silicon carbide substrate can be a limiting factor in the performance and cost of the semiconductor devices as will be disclosed in more detail herein below. The use of Silicon Carbide as a material for semiconductor devices has grown significantly due to its unique properties for withstanding high voltages and high temperatures. Thus, SiC has been deployed for power devices since its breakdown voltage is about ten times higher than silicon and the thermal conductivity of SiC is about three times higher than silicon. The high breakdown voltages supports the development of high voltage devices such as SBDs (Schottky Barrier Diodes), MOSFETs (Metal Oxide Semiconductor Field Effect Transistors), BJT (Bipolar Junction Transistors) and IGBTs (Insulated Gate Bipolar Transistors) by reducing the thickness of the drift region and thereby reducing the RDSₒₙ, which is a key parameter for high voltage devices. Compared to silicon devices, SiC devices can operate at higher switching frequencies thereby reducing switching losses. Thus, SiC can be operated at higher temperatures due to better thermal conductivity and has higher heat dissipation for removing heat which are desirable device characteristics.

The Insulated Gate Bipolar Transistor (IGBT) is a power switching transistor that combines the advantages of MOSFETs and BJTs (bipolar junction transistor) for use in power supply and motor control circuits. The IGBT structure incorporates both a MOSFET and BJT making it very suitable for a semiconductor switching device. The IGBT utilizes the advantages for the BJT and MOSFET transistors and combines them to form a device with superior performance when compared to each device separately. The IGBT uses the high input impedance and high switching speed of a MOSFET and the low saturation voltage of a bipolar transistor and combines them to produce the IGBT switching device that can handle large collector-emitter currents with virtually zero gate current drive. More specifically, the IGBT combines the insulated gate of the MOSFET with the output performance characteristics of a conventional bipolar transistor. The result of this combination is that the IGBT is voltage controlled like a MOSFET but has the output switching and conduction characteristics of a bipolar transistor. IGBTs are typically used in high voltage and high speed switching applications. These devices require thick layers of silicon carbide grown epitaxially with high quality (low defect density) for their implementation.

As mentioned previously, semiconductor devices such as MOSFETs, SBDs, and IGBTs among others are formed by using Silicon Carbide wafers as the starting substrate on which various layers are grown using epitaxy growth processes.

The epitaxial growth process for SiC is quite complicated because of the crystalline structure of SiC which has an atomic crystal that comprises 50% Silicon and 50% Carbon. Each carbon atom has exactly four silicon atoms as neighbors and vice versa which results in a very strong C—Si bond strength of approximately 4.6 eV. The silicon carbide crystal has lattice sites which can differ in their structures of nearest neighbors of silicon and carbon atoms. For example, these lattice sites can be either hexagonal or cubic sites. Thus, for silicon carbide, H stands for hexagonal lattices sites while C stands for cubic lattice sites. Furthermore, cubic and hexagonal lattice sites differ in their number of second nearest neighbors which results in the different electric fields at the specific site.

In addition, silicon carbide as a material is an example for polymorphism, in which the SiC crystal can grow in a wide range of crystal structures, also known as the polytypes. Each polytype has different electrical, optical, thermal, and mechanical properties that depend on the specific crystal structure. In the hexagonal close packed system for silicon carbide, each polytype is defined by the Si—C bilayer stacking sequence along the c-axis. Thus, each polytype is labeled after the number of stacking Si—C bi-layers in the unit cell and the lattice structure. Some of the common polytypes for SiC are 3C—SiC, 2H—SiC, 4H—SiC, and 6H—SiC.

In one embodiment, for high power, high voltage, or high switching speed devices, the polytype that is selected is the 4H-SiC because of its superior electrical properties such as high breakdown voltage and high electron mobility. Moreover, it is possible to grow high quality, single crystalline 4H—SiC wafers of large diameter (up to 200 mm) with low defect concentrations. The process of producing SiC wafers starts with the growth of SiC bulk crystals (called boules) grown from a seed crystal using the sublimation growth method, typically along the [0001] direction. Since the growth rate of the bulk crystal of SiC is quite slow and prone to defects, the usable length of the SiC boules are only between 30-50 mm. The process of producing SiC wafers from the SiC boules consist of slicing wafers that are sliced off-axis from the cylindrical boules. In one embodiment, the resulting off-axis 4H—SiC wafer is usually tilted 4 degrees towards the [1120] or [0001] direction to produce wafers with silicon carbide epitaxy with low defect density, as will be subsequently described.

For bipolar devices such as IGBTs, the quality of the epitaxy is critical from a device reliability perspective and requires careful consideration of the conditions for the growth of the required epitaxial layers. IGBTs and SiC bipolar transistors suffer from bipolar degradation where even a single basal plane dislocation can transform into a yield killing Single Stacking Fault (SSF) that is fatal for the electrical performance of the transistor device. SSFs between two partial dislocations are expanded during bipolar operation by gliding of partial dislocations leading to bipolar degradation and subsequent failure. By enabling growth of the epitaxial layers on the (1120) or A-plane of the 4H SiC substrate, basal plane dislocations can be avoided resulting in an epitaxial layer that is essentially defect free with high device reliability. While this approach is technically viable, the challenge is to implement this approach in a cost effective manner. Consequently, there is a need to produce high quality epitaxial layers for bipolar devices such as IGBTs that utilize the A-plane or (1120) with zero basal plane dislocations. In addition to using epitaxial layer growth in the A-plane, the same approach can be applied to substrates oriented in the M-plane (1100) and (1330) plane.

The figures subsequently describe an implementation of an IGBT in accordance with an example embodiment.

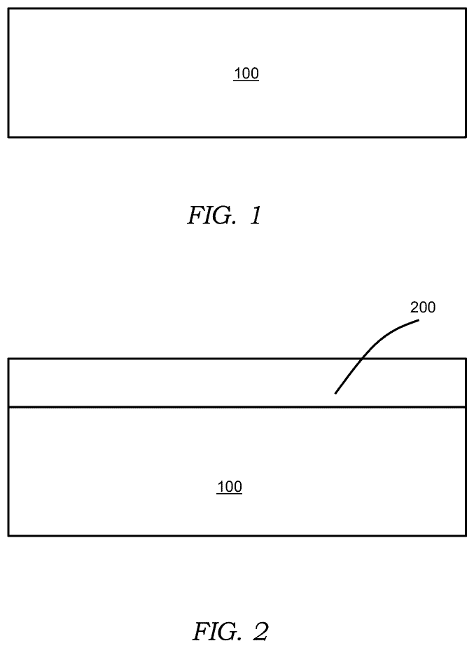

FIG. 1 is an illustration of a silicon carbide substrate (SiC) 100 in accordance with an example embodiment. In the example embodiment, silicon carbide substrate 100 is a silicon carbide wafer that is typically offcut by 4 degrees. Silicon carbide substrate 100 is used for the implementation of a semiconductor device such as an IGBT (Insulated Gate Bipolar Transistor). In the example embodiment, silicon carbide substrate 100 is used to grow low defect density epitaxial layers for the implementation of IGBTs using a combined MOSFET and BJT (bipolar junction transistor) device structure. To improve the performance of the IGBT, silicon carbide substrate 100 comprises a silicon carbide wafer along the A-plane as referenced to the silicon carbide crystal. Typically, a silicon carbide substrate 100 with an A-plane orientation is normally not used due to high cost. A method to reduce the silicon carbide substrate cost over many wafer fabrication cycles will be disclosed in detail herein below. The implementation of the IGBT using silicon carbide substrate 100 with the A-plane takes advantage of the enhanced surface mobility for the MOSFET structure as compared to the C-plane of the silicon carbide crystal. In general, silicon carbide substrate 100 comprises a 4H silicon carbide A-plane <1120> substrate used for the implementation of the IGBT. In one embodiment, silicon carbide substrate 100 comprises a N+ doped 4H silicon carbide A-plane <1120> substrate used for the implementation of the IGBT. In another embodiment, silicon carbide substrate 100 may comprise substrates in the M-plane (1100) and other planes such as (1330) plane. Although the example embodiment is illustrated with an IGBT, this invention may also be applied to other bipolar devices such as PIN diodes.

In one embodiment, silicon carbide substrate 100 may be a single side polished or double side polished wafer and can be considered as the parent wafer, for considerations that are described in subsequent process steps in the implementation of the current invention. In one embodiment, silicon carbide substrate 100 is the basic platform on which the example embodiment is implemented to support the process flow in accordance with the current invention. In one embodiment, silicon carbide substrate 100 is a reusable semiconductor substrate that is used for fabrication of semiconductor devices multiple times in accordance with the current invention. The reuse of silicon carbide substrate 100 many times for the implementation of semiconductor devices such as IGBT reduces the cost of manufacturing.

It should be noted that more than one IGBT will be fabricated on silicon carbide substrate 100. The device structure shown in detail herein below will be replicated across silicon carbide substrate 100. In one embodiment, each IGBT will be diced as individual die and packaged as an individual device. In general, the devices structures formed on or overlying silicon carbide substrate 100 will be separated from silicon carbide substrate 100. A surface of silicon carbide substrate 100 will be prepared after the separation. After the preparation and repair of the surface the silicon carbon substrate 100 can be reused for the manufacture of other devices or IGBTs as shown herein below.

FIG. 2 is an illustration of an epitaxial layer 200 overlying silicon carbide substrate 100 in accordance with an example embodiment. Epitaxial layer 200 is grown on or overlying the surface of silicon carbide substrate 100 using epitaxial vertical overgrowth in an epitaxial reactor. In an example embodiment, epitaxial layer 200 comprises a P+ doped layer grown with epitaxial vertical overgrowth over silicon carbide substrate 100 comprising a N+ silicon carbide wafer. The thickness of epitaxial layer 200 may be in the range of (0.1-4) micrometers and may be doped with boron and aluminum atoms and the doping of N+ doping may be in the range of (1e17-1e20)/cm² and may be doped by nitrogen or phosphorus atoms.

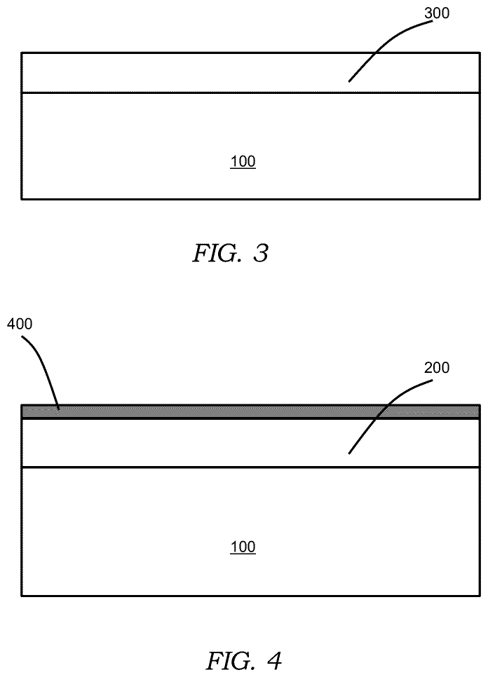

FIG. 3 is an illustration of an epitaxial layer 300 formed overlying silicon carbide substrate 100 in accordance with an example embodiment. In one embodiment, epitaxial layer 300 is P+ and is formed by implantation of P type species such as boron and aluminum into silicon carbide substrate 100 which is doped N+. The dose and implant energy used for epitaxial layer 300 is determined by the requirement of the semiconductor device that is subsequently formed. Epitaxial layer 300 is similar to epitaxial layer 200 of FIG. 2 but in this case, it is implanted and not grown using vertical epitaxial overgrowth. In general, the implementation disclosed in FIG. 3 is an equivalent alternative to forming an epitaxial layer overlying the surface of silicon carbide substrate 100.

FIG. 4 is an illustration of a hard mask layer 400 overlying epitaxial layer 200 in accordance with an example embodiment. Hard mask layer 400 is deposited overlying a surface of epitaxial layer 200 by using techniques such as CVD (Chemical Vapor Deposition), LPCVD (low pressure chemical vapor deposition), PECVD (Plasma Enhanced Chemical Vapor Deposition), APCVD (Atmospheric Pressure Chemical Vapor Deposition), SACVD (Sub Atmospheric Chemical Vapor Deposition) among other techniques. PVD (Physical Vapor Deposition), or ALD (Atomic layer Deposition) may also be used for hard mask layer 400. In the example implementation, hard mask layer 400 comprises PECVD (Plasma Enhanced Chemical Vapor Deposition) silicon oxide. The thickness of silicon oxide hard mask layer 400 is selected based on the requirements of subsequent processing steps as described in the example implementation and is in the range of 100-4000 nm. The thickness of hard mask layer 400 is determined by the specific requirements of the implementation and is well known to one skilled in the art. In another embodiment, a second hard mask layer may be deposited over hard mask layer 400. In one embodiment, hard mask layer 400 comprises PECVD silicon dioxide and the second hard mask layer may comprise PECVD deposited amorphous silicon. In another embodiment, hard mask layer 400 comprises a metal layer such as nickel. In other embodiments, multiple hard mask layers may be used.

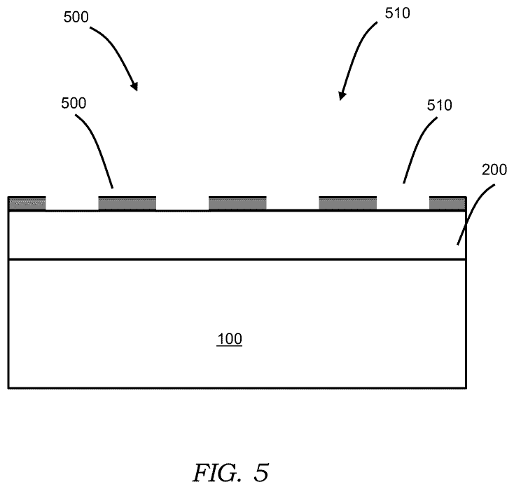

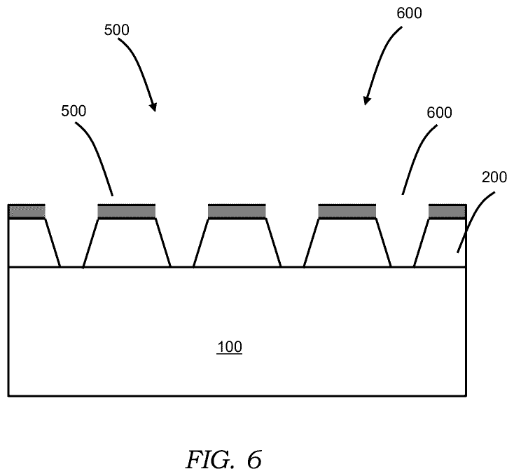

FIG. 5 is an illustration of a plurality of openings 510 formed in hard mask layer 400 of FIG. 4 in accordance with an example embodiment. In one embodiment, hard mask layer 400 of FIG. 4 is deposited overlying the surface of epitaxial layer 200 and is patterned to form plurality of openings 510 that expose areas of the surface of epitaxial layer 200. A patterned hard mask 500 remains after the patterning process. Plurality of openings 510 are formed in hard mask layer 400 of FIG. 4 by using methods of lithography and etching techniques commonly used in the semiconductor industry. In one embodiment, patterned hard mask 500 is left in areas to protect epitaxial layer 200 from being etched. The shape of plurality of openings 510 are determined by the requirements of epitaxial growth in subsequent steps in the implementation of the example embodiment. In one embodiment, plurality of openings 510 may be in the shape of squares or rectangles. In another embodiment, plurality of openings 510 may be in the shape of triangles, hexagons, or diamonds. The size of plurality of openings 510 may be in the range of (20-500) nanometers (nm) and may be linearly arrayed or staggered and determined by the requirements of epitaxial overgrowth in the subsequent steps of fabrication of the example device. In one embodiment, spacing between adjacent openings of plurality of openings 510 is determined by the requirements of epitaxial overgrowth in the subsequent steps of fabrication of the example device and can be in the range of 500 nm to 5 micrometers (um). Plurality of openings 510 are generated on a surface of hard mask layer 400 of FIG. 4 by using lithography techniques that are well known to those skilled in the art. In one embodiment, plurality of openings 510 are implemented using optical lithography using UV, DUV or EUV. In another embodiment, plurality of openings 510 are implemented using an electron beam direct write technique. In yet another embodiment, plurality of openings 510 are implemented using Nano-Imprint Lithography (NIL). In another embodiment, plurality of openings 510 are implemented using Direct Laser Write.

In one example embodiment, plurality of openings 510 are implemented by first coating a surface of hard mask layer 400 of FIG. 4 with a photosensitive layer of photoresist, which may be positive or negative in its chemistry. In the example embodiment, positive photoresist is used in coating the surface of hard mask layer 400 of FIG. 4. An optical tool called a stepper is used to transfer the pattern of openings on to the positive photoresist layer using chemistries that are well known to those skilled in the art. The choice of the photoresist layer, thickness of the photoresist layer, the exposure and develop times for the subsequent chemical steps are well known to those skilled in the art and determined by the requirements of accurate pattern transfer from the photoresist layer to hard mask layer 400 of FIG. 4 to subsequently form plurality of openings 510 and leave patterned hard mask 500. The stepper transfers the pattern of plurality of openings 510 to cover the surface of hard mask layer 400 of FIG. 4 overlying fist epitaxial layer 200. In one embodiment, plurality of openings 510 cover an entire surface or substantially all of the surface of epitaxial layer 200 overlying silicon carbide substrate 100.

After the pattern transfer is completed using lithography, the next step is the patterning of hard mask layer 400 of FIG. 4 using etching techniques to selectively remove hard mask layer 400 of FIG. 4 thereby leaving patterned hard mask 500 overlying epitaxial layer 200. The selective removal of hard mask layer 400 of FIG. 4 to form patterned hard mask 500 may use Reactive Ion Etching (RIE). Different gases may be used to form a plasma to selectively remove the portions of hard mask layer 400 of FIG. 4 exposed by the patterned photoresist. The choice of gases for the RIE is determined by hard mask layer 400 of FIG. 4 used in the implementation. In the example embodiment, with a silicon oxide used as hard mask layer 400, fluorine-based chemistries such as SF₆, CF₄, CHF₃, and other gases may be used in the RIE. Accordingly, in the example embodiment with silicon oxide as hard mask layer 400, plurality of openings 510 are etched in hard mask layer 400 of FIG. 4 using a fluorine-based chemistry that exposes the surface of epitaxial layer 200. Patterned hard mask 500 remains in areas overlying epitaxial layer 200 to protect or mask the surface of epitaxial layer 200 from etching. After patterning hard mask layer 400, the photoresist is stripped using techniques well known to those skilled in the art and may be dry, wet or a combination of dry and wet processing.

FIG. 6 is an illustration of a plurality of openings 600 formed in epitaxial layer 200 in accordance with an example embodiment. Plurality of openings 600 are formed after hard mask layer 400 of FIG. 4 is etched to form plurality of openings 510 in FIG. 5. In one embodiment, the surface of epitaxial layer 200 exposed by plurality of openings 510 of FIG. 5 is then etched to form plurality of openings 600 using RIE (Reactive Ion Etching). In one embodiment, epitaxial layer 200 is etched using patterned hard mask 500 of FIG. 5 to form plurality of openings 600 with an aspect ratio that is determined by the requirements of epitaxial growth in subsequent processing of the example device. In one embodiment, an inductively coupled plasma (ICP) with high density may also be used to form plurality of openings 600 in epitaxial layer 200. In one embodiment, plurality of openings 600 may be tapered such that the bottom of plurality of openings 600 are smaller than the top of the openings defined by patterned hard mask 500 of FIG. 5. In another embodiment, epitaxial layer 200 may be etched through its complete thickness to expose surface of silicon carbide substrate 100. In another embodiment, plurality of openings 600 in epitaxial layer 200 may be made such that a portion of thickness of epitaxial layer 200 remains over silicon carbide substrate 100.

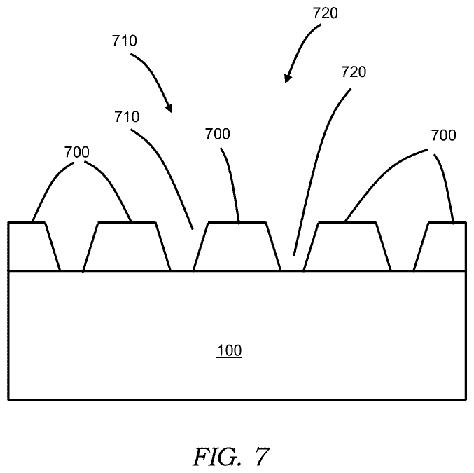

FIG. 7 is an illustration of a plurality of pillars 700 formed in epitaxial layer 200 in accordance with an example embodiment. Plurality of pillars 700 are shown after the removal of patterned hard mask 500 of FIG. 6. In an example embodiment, patterned hard mask 500 of FIG. 6 is removed by using wet or dry chemical etching and is determined by the choice of hard mask layer material. In the example embodiment, patterned hard mask 500 of FIG. 6 comprises a PECVD silicon oxide that is removed using a wet chemistry of BHF (Buffered Hydrofluoric Acid). Other solutions for etching PECVD silicon oxide may include HF (Hydrofluoric Acid) in various dilutions in water. Silicon carbide substrate 100 and epitaxial layer 200 are then cleaned in preparation for the next step in the fabrication of the example device. In one embodiment, the pattern of plurality of pillars 700 are shaped as triangles or hexagons to expose (1120) or equivalent crystal planes since these orientations facilitate high quality epitaxial overgrowth with low defect density in subsequent processing steps in accordance with the current invention. In one embodiment, a height 710 of plurality of pillars 700 is in the range of (500-5000) nm and spacings 720 between adjacent pillars is in the range of (500-5000) nm and is determined by the requirements of silicon carbide epitaxy as subsequently described herein. In one embodiment, spacings 720 between plurality of pillars 700 is formed by etching a plurality of trenches into epitaxial layer 200. The plurality of trenches are etched in a pattern that yields plurality of pillars 700. In one embodiment, the profile of plurality of pillars 700 may be tapered so that it is wider at a base of a pillar that couples to silicon carbide substrate 100 and narrower towards a surface of the pillar of the plurality of pillars 700. In one embodiment, the pillars may be tapered from the base to come to a point at the surface of the pillar of the plurality of pillars 700.

Subsequent figures disclosed herein below will describe an exfoliation process to separate one or more high quality epitaxial layers from silicon carbide substrate 100. In one embodiment, one or more semiconductor devices are formed in or on the one or more high quality epitaxial layers prior to implementing the exfoliation process. The separation of the one or more high quality epitaxial layers allows the reuse of silicon carbide substrate 100 in wafer processing of the formation of new semiconductor devices such as IGBTs. Alternatively, in one embodiment, there may only be need for a process to grow one or more high quality epitaxial layers overlying silicon carbide substrate 100 without exfoliation. The process for growing high quality epitaxial layers overlying silicon carbide substrate 100 will comprise a step of growing silicon carbide epitaxially by lateral epitaxial overgrowth on silicon carbide substrate 100 with plurality of pillars 700. In one embodiment, 4H—SiC growth will occur along the <1120> or <1100> directions due to the lateral epitaxial growth. In one embodiment, the lateral epitaxial overgrowth comprises growth from sidewalls of each pillar of the plurality of pillars 700. In one embodiment, lateral epitaxial overgrowth from the sidewalls from each pillar of the plurality of pillars 700 will merge comprising merged epitaxial lateral overgrowth (MELO) that is high quality low defectivity epitaxy. In one embodiment, the merged epitaxial lateral overgrowth (MELO) from the lateral epitaxial overgrowth process will form a continuous epitaxial layer overlying a vertical 4H—SiC growth in spacing 720 between plurality of pillars 700. This merged epitaxial lateral growth is possible by controlling height 710 of plurality of pillars 700 and spacings 720 between adjacent pillars in plurality of pillars 700 to form a high quality SiC epitaxial layer with low defect density. In one embodiment, the high quality SiC epitaxial layer prevents a propagation of dislocation defects from silicon carbide substrate 100. In one embodiment, silicon carbide substrate 100 comprises 4H silicon carbide A-plane <1120> substrate and the device fabricated on silicon carbide substrate 100 is a plurality of IGBTs (insulated gate bipolar transistors) overlying the epitaxial layer comprising MELO with a high quality and low defectivity.

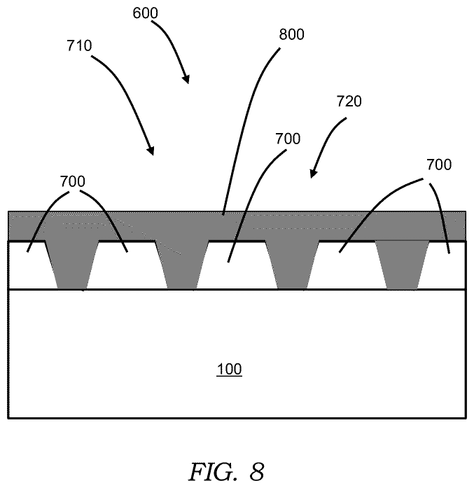

FIG. 8 is an illustration of a refill layer 800 formed over plurality of pillars 700 in accordance with an example embodiment. Refill layer 800 also forms in openings 600 after removal of patterned hard mask 500 of FIG. 5. In one embodiment, refill layer 800 is formed overlying plurality of pillars 700 and in openings 600. In one embodiment, refill layer 800 is a carbon layer. In another embodiment, refill layer 800 is a polymer layer that is deposited and then subsequently converted into a carbon layer. In another embodiment, refill layer 800 is a tantalum carbide layer. In general, refill layer 800 is a layer that can subsequently be targeted specifically after further wafer processing is performed. In one embodiment, refill layer is targeted to be heated, thus refill layer 800 can be a selectively heatable material. For example, refill layer 800 can be selectively heated by a laser in a subsequent step which will be described in further detail herein below.

Refill layer 800 can be formed over plurality of pillars 700 and in openings 600 after removal of patterned hard mask 500 using different methods and processes.

In one embodiment, refill layer 800 is formed by spin coating a polymer layer and then subsequently converting it into a carbon layer by pyrolysis in an inert environment. In another embodiment, refill layer 800 is formed by CVD (Chemical Vapor Deposition) of a polymer layer such as Parylene and subsequently converting the deposited polymer layer into carbon by heating it at a high temperature of (900-1400) °C in an inert environment such as nitrogen. In another embodiment, refill layer 800 may be formed by sputter deposition using a carbon target. Other methods of carbon deposition may include CVD (chemical vapor deposition), ALD (Atomic layer Deposition) or PVD (Physical Vapor Deposition) to form refill layer 800.

In an example embodiment, refill layer 800 is formed by spin coating a photoresist layer. The photoresist layer may be a positive polarity or negative polarity photoresist. The choice of thickness of the photoresist layer is determined by the height 710 of plurality of pillars 700 and the final thickness of refill layer 800 required by the process. The final thickness of the spin-coated photoresist is determined by the choice of the viscosity of the photoresist and the spread and spin speed during the dispense of the photoresist. The spin-coated photoresist is then baked in a nitrogen environment at a temperature of (90-120) °C to drive out solvents. In the pyrolysis process, silicon carbide substrate 100 having plurality of pillars 700 coated with a photoresist layer is placed in a furnace and heated to (900-1400) °C in an inert environment of nitrogen or in forming gas (nitrogen with hydrogen) to convert the spin-coated photoresist to carbon. During the pyrolysis process, the spin coated photoresist layer is converted into carbon while undergoing volumetric shrinkage. In the example embodiment, the pyrolysis process converts the spin-coated photoresist to carbon while also shrinking to form refill layer 800. In another embodiment, the spin-coated photoresist layer thickness may be modified by etching in an oxygen plasma after the spin-coating and prior to the pyrolysis process.

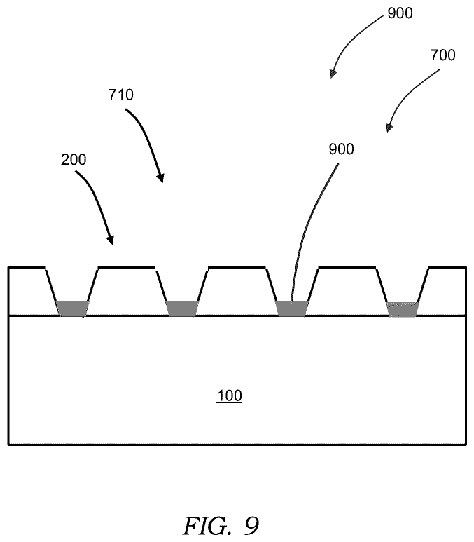

FIG. 9 is an illustration of an exfoliation layer 900 formed between plurality of pillars 700 in accordance with an example embodiment. Exfoliation layer 900 is used in the epitaxial growth processes overlying silicon carbide substrate 100 as will be subsequently described herein below. In one embodiment, exfoliation layer 900 is formed by reducing the thickness of refill layer 800 of FIG. 8 using an etching process. In one embodiment, refill layer 800 of FIG. 8 is a carbon layer and is etched using RIE (Reactive Ion Etching) to form exfoliation layer 900. In one embodiment, a height of refill layer 800 is reduced to a predetermined height to form exfoliation layer 900. In one embodiment, exfoliation layer 900 is less than a height 710 of each pillar of plurality of pillars 700. The predetermined height is achieved by RIE using oxygen, argon, and other gases, as well known to those skilled in the art. In one embodiment, the predetermined height of exfoliation layer 900 is in a range of (300-1000) nanometers (nm).

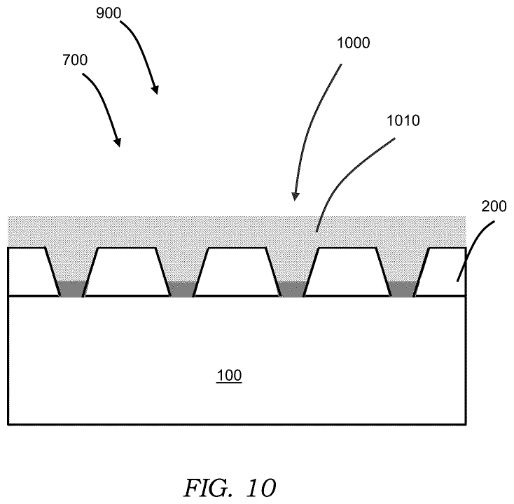

FIG. 10 is an illustration of a merge layer 1000 formed in silicon carbide substrate 100 in accordance with an example embodiment. In the example embodiment, merge layer 1000 comprises an epitaxial layer formed by on-axis epitaxial lateral overgrowth over plurality of pillars 700 overlying exfoliation layer 900 and silicon carbide substrate 100. In one embodiment, merge layer 1000 comprises an epitaxial layer 1010 that is formed by epitaxial lateral overgrowth overlying plurality of pillars 700. In one embodiment, epitaxial layer 1010 is a P+ layer and is in the range of (1e17-1e20)/cm². In one embodiment, merge layer 1000 has a surface that overlies a surface of substrate 100.

Merge layer 1000 is an epitaxial layer having very low defectivity propagating from the surface of plurality of pillars 700. In one embodiment, merge layer 1000 has a defectivity less than silicon carbide substrate 100. In one embodiment, merge layer 1000 is formed with very low basal plane dislocations (BPD) propagating from the surface of epitaxial layer 200 of FIG. 2 with 4H A-plane <1120> crystalline orientation. In addition, the density of defects is further reduced by lateral epitaxial overgrowth from the top surface of plurality of pillars 700 and sidewalls of plurality of pillars 700 resulting in a epitaxial layer 1010 forming merge layer 1000 with extremely low density of defects making it suitable for formation of semiconductor devices such as IGBTs. In the formation of merge layer 1000, the epitaxial growth process between plurality of pillars 700 is inhibited by exfoliation layer 900 such that the lateral epitaxial overgrowth is enabled from the top surface and sidewalls of plurality of pillars 700 resulting in a merging of epitaxial fronts from adjacent pillars of plurality of pillars 700. This results in the formation of a continuous epitaxial layer that is virtually free of basal plane dislocations as well as other crystal defects in silicon carbide epitaxial growth processes such as stacking faults, threading dislocations, edge dislocations among other defects. The merged epitaxial lateral overgrowth (MELO) results in formation of merge layer 1000 with very low density of defects making it suitable for formation of epitaxial layers for very high voltage semiconductor devices such as high voltage IGBTs. The extremely low defect density of defects in merge layer 1000 results in high reliability operation of high voltage semiconductor devices which are very sensitive to epitaxial defects in the epitaxial layers used in the fabrication of these devices such as IGBTs. In one embodiment, merge layer 1000 comprises a p+ silicon carbide epitaxial layer 1010 formed by merged epitaxial lateral overgrowth, plurality of pillars 700, and exfoliation layer 900. In one embodiment, merge layer 1000 overlies silicon carbide substrate 100 comprising a N+ silicon carbide wafer. In one embodiment, the surface of merge layer 1000 has a defectivity less than 10⁴ per square centimeter that is achieved by increasing the surface of epitaxial layer 1010 and decreasing a top surface of each pillar of plurality of pillars 700 that forms the surface of merge layer 1000. In one embodiment, merge layer 1000 forms a contiguous surface overlying the surface of silicon carbide substrate 100 to support the formation of low defectivity epitaxial layers of different thicknesses thereafter.

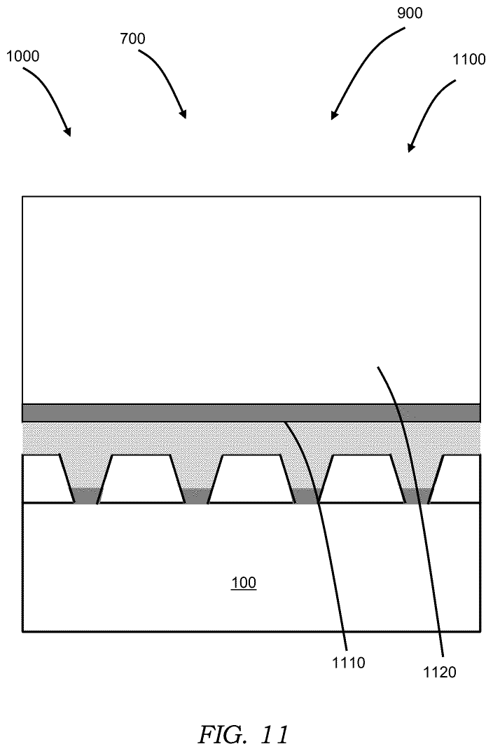

FIG. 11 is an illustration of an epitaxial layer 1100 overlying merge layer 1000 in accordance with an example embodiment. In the example embodiment, epitaxial layer 1100 is grown overlying merge layer 1000 to facilitate the formation of semiconductor devices such as IGBTs using suitable fabrication process. Epitaxial layer 1100 is grown overlying merge layer 1000 by vertical epitaxial growth in an epitaxial reactor. The thickness of epitaxial layer 1100 may be in the range of 20-200 microns and is determined by the performance requirements of the semiconductor devices formed in epitaxial layer 1100. Epitaxial layer 1100 may be doped either n-type or p-type based on the electrical device characteristics of the semiconductor devices formed in epitaxial layer 1100. In one embodiment, epitaxial layer 1100 comprises two epitaxial layers which are sequentially grown overlying merge layer 1000 and has a different doping polarity from merge layer 1000. In one embodiment, epitaxial layer 1100 comprises epitaxial layer 1110 overlying merge layer 1000 and epitaxial layer 1120 overlying epitaxial layer 1110. In one embodiment, epitaxial layer 1110 comprises a n+ doped epitaxial layer forming a buffer layer overlying merge layer 1000 comprising a p+ doped epitaxial layer. In the example embodiment, merge layer 1000 comprises the p+ doped epitaxial layer 1110 overlying plurality of pillars 700 and merged from sidewall growth between adjacent pillars of plurality of plurality of pillars 700 thereby forming the merged epitaxial lateral overgrowth (MELO). In the example embodiment, merge layer 1000 layer overlies exfoliation layer 900 that overlies silicon carbide substrate 100. In the one embodiment, silicon carbide substrate 100 comprises a N+ doped silicon carbide wafer. In one embodiment, epitaxial layer 1120 comprises a n-doped epitaxial layer overlying the buffer layer comprising n+ doped epitaxial layer 1110. Epitaxial layer 1120 comprises a drift layer used for the formation of high voltage semiconductor devices such as IGBTs. The thickness of epitaxial layer 1120 may be in the range of (20-200) microns and is determined by the voltage requirements of the semiconductor devices formed in epitaxial layer 1100. In one embodiment, epitaxial layer 1120 is doped n-type and is about 100 microns thick for a IGBT operating above 10 KV.

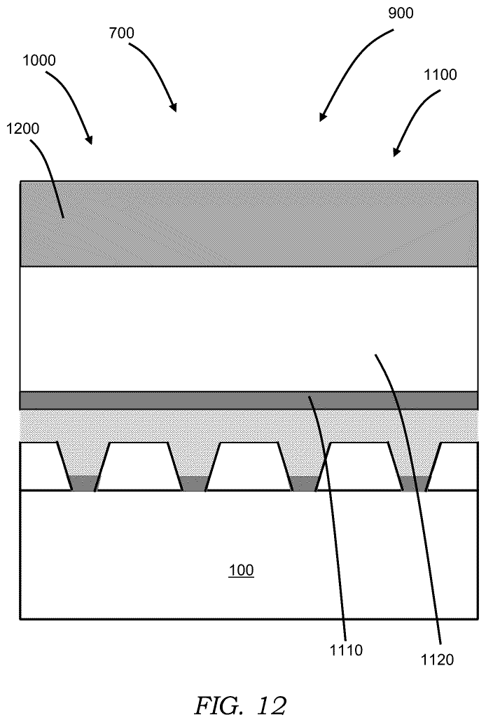

FIG. 12 in an illustration of a current spreading layer 1200 in epitaxial layer 1120 in accordance with an example embodiment. Current spreading layer 1200 is formed in epitaxial layer 1120 by implanting dopants into a surface of epitaxial layer 1120 and then subsequently activating the dopants by a furnace anneal. In one embodiment, the thickness of current spreading layer 1200 may be in the range of (0.1-3) micrometers and is determined by the electrical performance requirements of the semiconductor device that is formed in subsequent process steps. In the example embodiment, current spreading layer 1200 is meant to reduce the density of mobile carriers in the drift region and prevent current crowding by relaxing the concentration of the current distribution at the top of the drift region of the IGBT. The static and dynamic characteristics of the IGBT can be improved by adjusting the doping concentration of current spreading layer 1200 and also by adjusting the thickness of current spreading layer 1200.

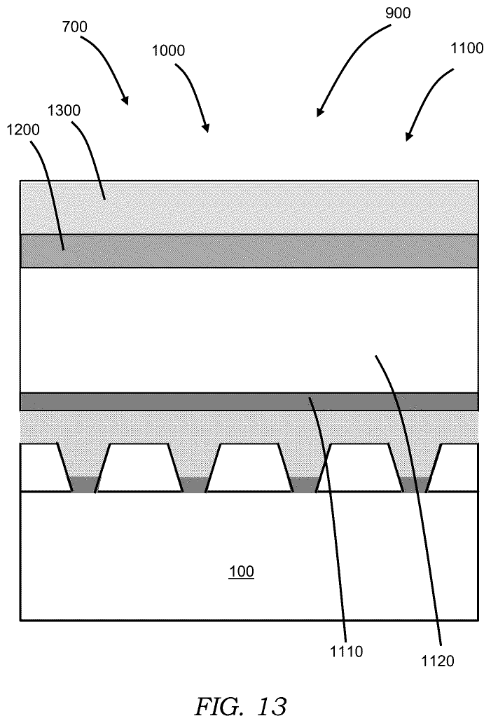

FIG. 13 is an illustration of a body implant layer 1300 in epitaxial layer 1120 in accordance with an example embodiment. Body implant layer 1300 is formed in epitaxial layer 1120 by implanting dopants of the opposite polarity to epitaxial layer 1120 and then activating the dopants. In the example embodiment, epitaxial layer 1120 is doped n-type and body implant layer 1300 is doped p-type. In the example embodiment, body implant layer 1300 is doped p-type to enable formation of a n-channel MOSFET of an IGBT with a n-type doped epitaxial layer 1120 as will be disclosed further herein below.

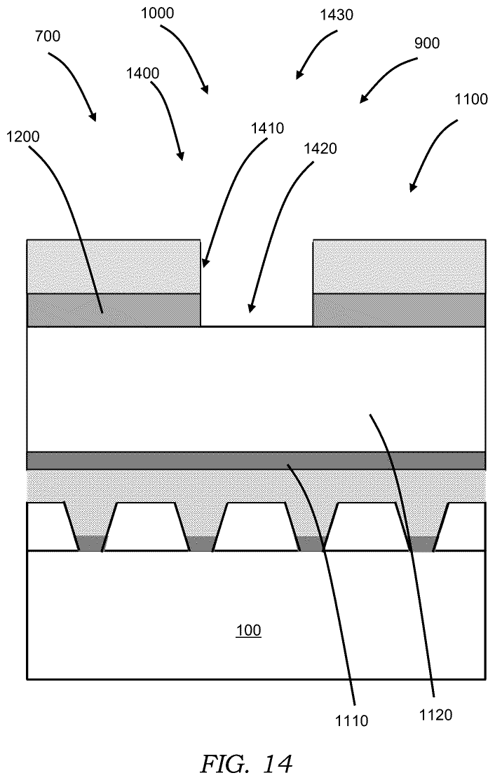

FIG. 14 is an illustration of an opening 1400 exposing epitaxial layer 1120 in accordance with an example embodiment. Opening 1400 forms a trench 1430 that removes a portion of body implant layer 1300 and a portion of current spreading layer 1200. Trench 1430 formed by opening 1400 has a bottom 1420 and walls 1410. In the example embodiment, opening 1400 has walls 1410 that is vertical and bottom 1420 that is substantially planar. In the example embodiment, opening 1400 is formed by patterning and etching a portion of body implant layer 1300 and a portion of current spreading layer 1200 by using lithography to define the pattern and using RIE (Reactive Ion Etching) to form trench 1430 to expose a portion of epitaxial layer 1120. In one embodiment, opening 1400 may be formed by deposition of a hard mask, patterning the hard mask to expose surface of body implant layer 1300 and then using RIE to remove a portion of body implant layer 1300 and current spreading layer 1200 to expose a surface of epitaxial layer 1120. The hard mask layer is then removed after opening 1400 is formed.

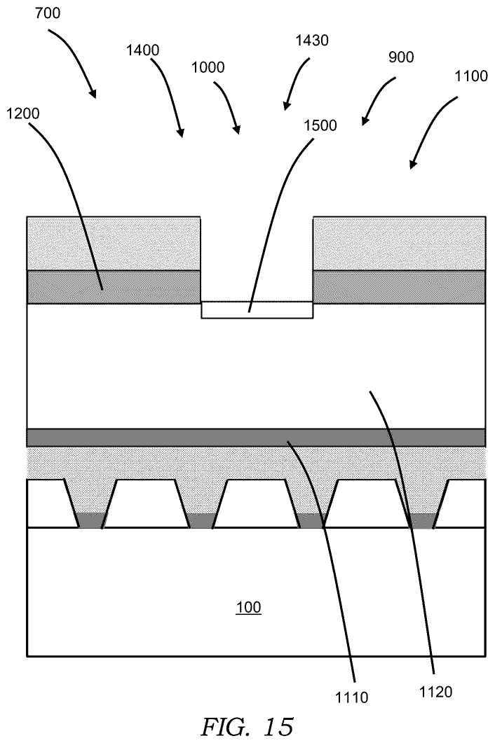

FIG. 15 is an illustration of an implant layer 1500 formed on bottom 1420 of trench 1430 in accordance with an example embodiment. Implant layer 1500 is formed by implanting dopants of an opposite polarity of epitaxial layer 1120. In the example embodiment, epitaxial layer 1120 is n-type and implant layer 1500 is p-type. Implant layer 1500 is a shield layer formed to improve the electrical performance of the trench MOSFET of the IGBT that is formed in subsequent fabrication steps.

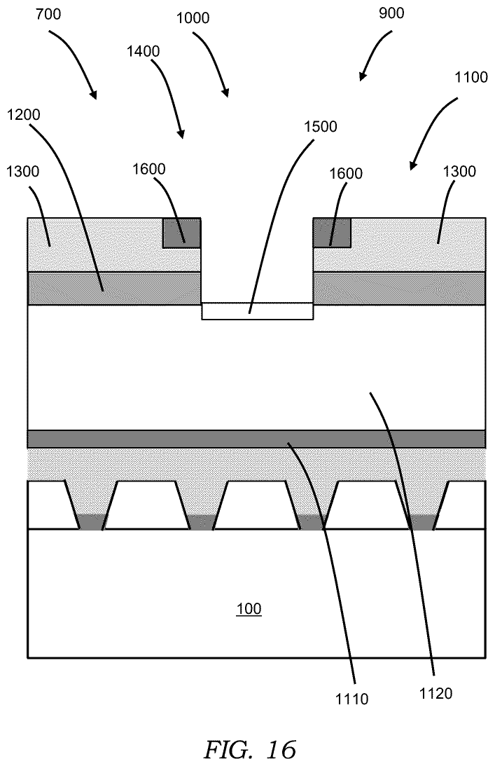

FIG. 16 is an illustration of source regions 1600 formed in body implant layer 1300 in accordance with an example embodiment. Source regions 1600 are selectively formed in body implant layer 1300 by implanting dopants through a mask that are of the opposite polarity than body implant layer 1300. Source regions 1600 formed in body implant layer 1300 serve as the source electrode of a MOSFET of the IGBT that is formed in subsequent fabrication steps. In one embodiment, source regions 1600 are formed by implanting n-type dopants through a mask into body implant layer 1300 that is doped p-type.

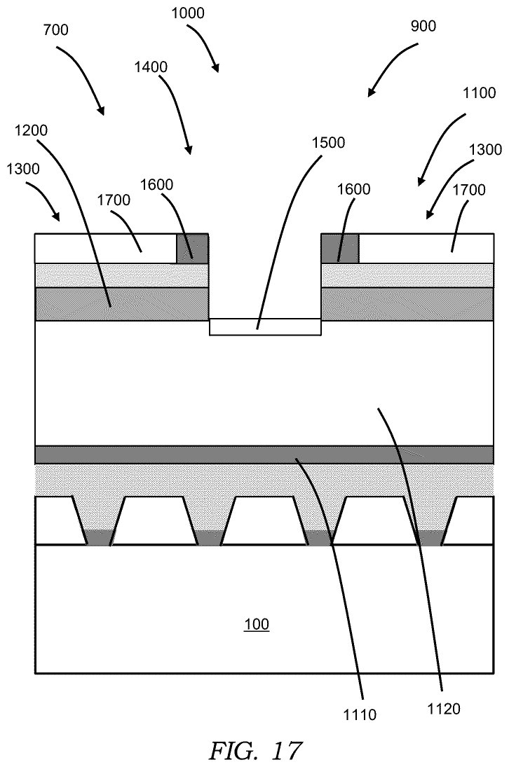

FIG. 17 is an illustration of an implant layer 1700 formed adjacent to source regions 1600 in accordance with an example embodiment. Implant layer 1700 is formed by implanting dopants through a mask that has a polarity that is opposite to that of source regions 1600. In an example embodiment, implant layer 1700 is formed by implanting p-type dopants adjacent to source regions 1600 that are doped n-type in a MOSFET of an IGBT that is formed in subsequent fabrication steps.

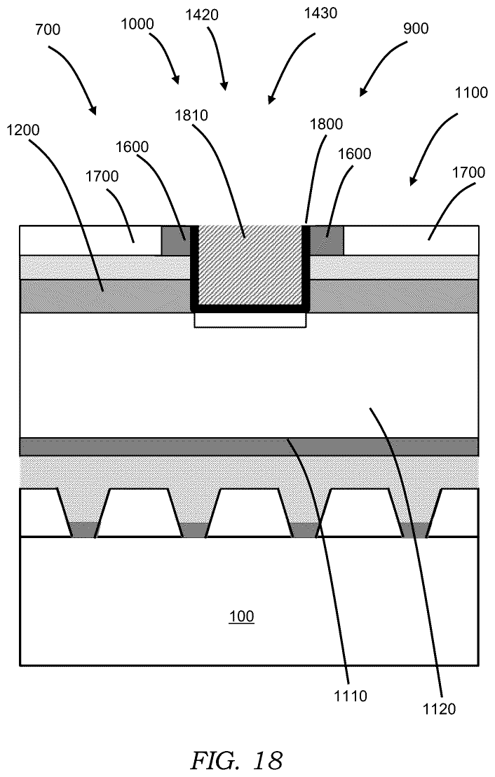

FIG. 18 is an illustration of a gate oxide 1800 and a gate electrode 1810 formed in accordance with an example embodiment. In the example embodiment, gate oxide 1800 is formed overlying walls 1410 of trench 1430 corresponding to opening 1400 of FIG. 17 and is gate oxide 1800 is formed on bottom 1420 of trench 1430. In one embodiment, gate oxide 1800 is formed by deposition. The thickness of gate oxide 1800 is (200-500) Angstroms and may be composed of one or more layers of gate dielectric materials. In one embodiment, gate electrode 1810 is formed by depositing a gate electrode layer that is electrically conducting. In one embodiment, gate electrode 1810 is formed by depositing doped LPCVD polysilicon overlying gate oxide 1800. The LPCVD polysilicon layer forming gate electrode 1810 may be doped n-type or p-type The thickness of gate electrode 1810 is chosen to completely refill opening 1400 and may be in the range of (0.3-2) micrometers. Portions of the LPCVD polysilicon layer of gate electrode 1810 deposited on a surface of source regions 1600 and a surface of implant layer 1700 are subsequently removed. In the example embodiment, the surfaces of source regions 1600 and implant layer 1500 are substantially planar to a surface of gate electrode 1810. The removal of portions of layer of gate electrode 1810 deposited on surface of source regions 1600 and implant layer 1700 may be done using CMP or by RIE.

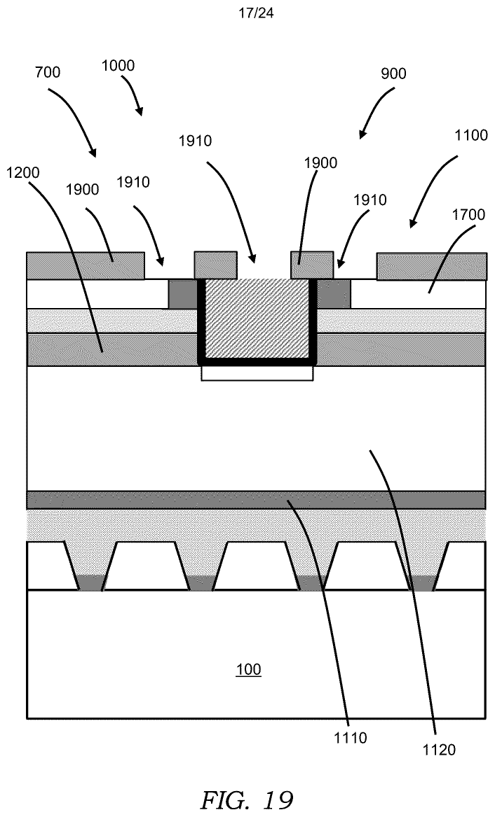

FIG. 19 is an illustration of a dielectric isolation layer 1900 with a plurality of contact openings 1910 in accordance with an example embodiment. Dielectric isolation layer 1900 is deposited by using PECVD Silicon Dioxide, PECVD Silicon Nitride, PECVD, or Silicon Oxynitride among other films. In one embodiment, the thickness of dielectric isolation layer 1900 is in a range of (1-4) micrometers. In an example embodiment, dielectric isolation layer 1900 is PECVD Silicon Oxide and is approximately one micrometer thick. In one embodiment, dielectric isolation layer 1900 is formed by oxidation of the layer of gate electrode 1810 of FIG. 18 formed by deposition of doped LPCVD polysilicon. In another embodiment, dielectric isolation layer 1900 may be formed by deposition of multiple layers of dielectric isolation layers.

In the example embodiment, dielectric isolation layer 1900 is patterned and etched to form plurality of contact openings 1910. In the example embodiment, dielectric isolation layer 1900 is patterned and etched to form openings 1910 so as to enable contact with the source and gate of the MOSFET.

In one embodiment, photolithography techniques and etching of dielectric isolation layer 1900 to form contact openings 1910 are done using RIE (Reactive Ion Etching), wet etching or a combination of etching steps. In an example embodiment, contact openings 1910 are patterned using a stepper and etched using RIE.

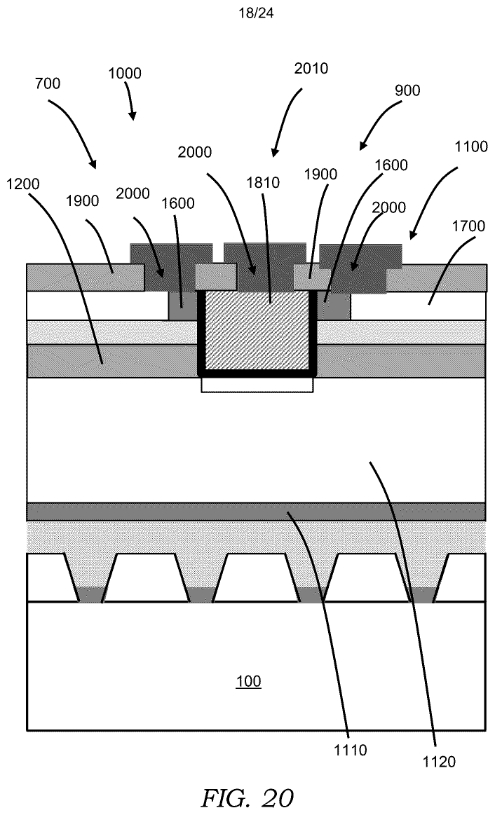

FIG. 20 is an illustration of a plurality of metal contacts 2000 formed in accordance with an example embodiment. In the example embodiment, metal contacts 2000 are meant to enable electrical connections to the source and gate electrodes of the MOSFET. Metal contacts 2000 makes electrical contact with source regions 1600 and gate electrode 1810. Metal contacts 2000 can be formed by deposition of a metal layer using sputtering, e-beam evaporation, electrodeposition among other techniques and can also use a combination of metal deposition techniques. The metal layer may be patterned using lithography and etched to form metal contacts 2000.

In addition, lift-off techniques may also be used for the deposition and patterning of the metal layer to form metal contacts 2000, as will be evident to those skilled in the art. The metal layer forming metal contacts 2000 may be annealed or sintered to ensure good ohmic contact with source and gate regions of the MOSFET.

After formation of metal contacts 2000, a passivation layer may be deposited and patterned to expose bond pads of gate and source electrodes of the MOSFET. At this stage, in the example embodiment, the fabrication of an IGBT 2010 using silicon carbide substrate 100 with improved electrical performance is complete where a MOSFET is electrically coupled with a BJT using the fabrication process described in FIGS. (3-20). In the example embodiment, while the implementation of a single IGBT is described, it will be understood by those skilled in the art that a plurality of IGBTs can be formed in an array on silicon carbide substrate 100 using the same fabrication processes. In one embodiment, the plurality of IGBTs will be diced into individual chips, packaged, and tested as individual devices.

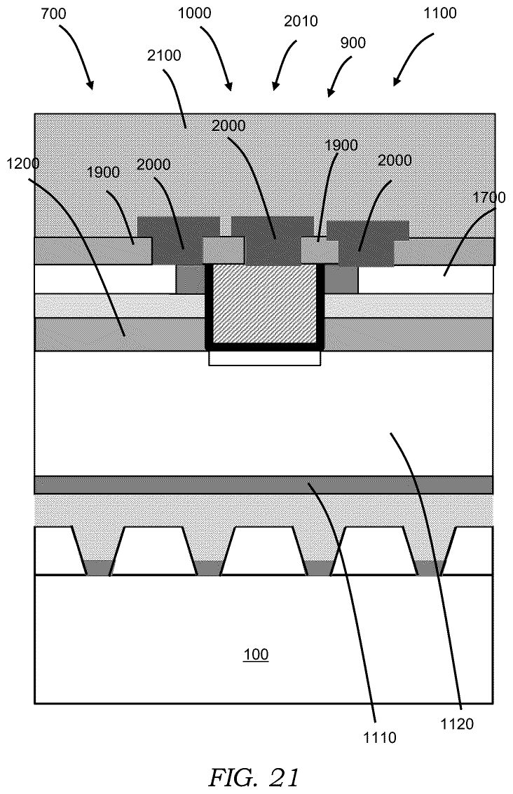

FIG. 21 is an illustration of a carrier wafer 2100 attached to IGBT 2010 formed in silicon carbide substrate 100 in accordance with an example embodiment. Silicon carbide substrate 100 with IGBT 2010 is temporarily coupled to carrier wafer 2100 to enable an exfoliation process which is subsequently described. The exfoliation process enables the separation of a portion of silicon carbide substrate 100 with IGBT 2010 to be separated from the major portion of silicon carbide substrate 100.

In one embodiment, silicon carbide substrate 100 with IGBT 2010 is attached to carrier wafer 2100 by adhesives such as UV sensitive glue among others. Carrier wafer 2100 may be borosilicate glass which is UV transparent and may be used with a UV curable adhesive for the bonding.

The exfoliation process occurs at an exfoliation plane comprising plurality of pillars 700 from FIG. 7 and exfoliation layer 900 of FIG. 9. Exfoliation layer 900 is between plurality of pillars 700 in silicon carbide substrate 100. IGBT 2010 is formed in epitaxial layer 1100 overlying merge layer 1000. In one embodiment, the exfoliation plane is below a top surface of plurality of pillars 700 and on a plane corresponding to exfoliation layer 900. In the example embodiment, the plane of exfoliation will occur at approximately exfoliation layer 900 such that silicon carbide substrate 100 has a new surface below the previous surface in which the plurality of pillars 700 are formed.

Different methods of exfoliation may be used to separate a portion of silicon carbide substrate 100 with IGBT 2010 from a major portion of silicon carbide substrate 100. In an example embodiment, a laser or lasers may be used for the exfoliation. In the example embodiment, one or more lasers that are substantially transparent to Silicon Carbide is focused though the backside of silicon carbide substrate 100 on exfoliation layer 900. As previously mentioned, the exfoliation plane comprises plurality of pillars 700 from FIG. 7 and exfoliation layer 900 between plurality of pillars 700 in silicon carbide substrate 100. In the example embodiment, exfoliation layer 900 comprises carbon. The energy from the laser is selectively coupled to exfoliation layer 900 comprising carbon between plurality of pillars 700 in silicon carbide substrate 100. In one embodiment, the laser rapidly heats the carbon of exfoliation layer 900 thereby producing a thermal shock that fractures pillars adjacent to the heated carbon of plurality of pillars 700 in silicon carbide substrate 100. The fracture in plurality of pillars 700 of FIG. 7 due to thermal shock causes a portion of silicon carbide substrate 100 with IGBT 2010 to be exfoliated from the major portion of silicon carbide substrate 100.

In the example embodiment, as a result of the exfoliation process, IGBT 2010 formed in epitaxial layer 1100, along with merge layer 1000, and a portion of silicon carbide substrate 100 above exfoliation layer 900 will remain with carrier wafer 2100. Thus, the major portion of silicon carbide substrate 100 is physically separated from IGBT 2010 by the exfoliation process. As mentioned previously, in the example embodiment, a plurality of IGBTs are formed at the same time as IGBT 2010 on silicon carbide substrate 100. In the example embodiment, exfoliation layer 900 and plurality of pillars 700 overlies silicon carbide substrate 1000. Thus, the exfoliation process separates all of the IGBTs formed overlying silicon carbide substrate 100 from a remaining silicon carbide substrate. Thus, when discussing separation of IGBT 2010 it corresponds to the separation of all IGBTs formed overlying silicon carbide substrate 1000.

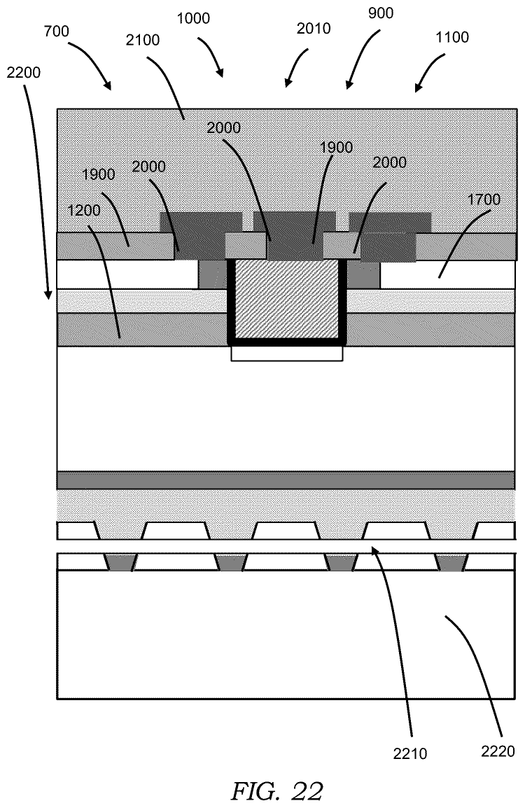

FIG. 22 is an illustration of a portion of silicon carbide substrate 2200 after the exfoliation process in accordance with an example embodiment. In the example embodiment, the separation of silicon carbide substrate 2200 using a laser causes a fracture plane 2210 leaving IGBT 2010 and the portion of silicon carbide substrate 100 coupled with carrier wafer 2100 and the major portion of silicon carbide substrate 100 separated below fracture plane 2210.

In the example embodiment, silicon carbide substrate 2200 comprises IGBT 2010 formed in silicon carbide epitaxial layer 1100 overlying silicon carbide merge layer 1000. Thus, silicon carbide substrate 2200 comprises primarily of silicon carbide epitaxial layers grown in an epitaxial reactor and is temporarily coupled to carrier wafer 2100 for the exfoliating process. Silicon carbide substrate 2220 comprises the major portion of silicon carbide substrate 100 of FIG. 21 that remains after the exfoliation process. Silicon carbide substrate 2220 is then subsequently processed for re-use for formation of semiconductor devices such as IGBTs two or more times.

In general, fracture plane 2210 is substantially in the same plane where exfoliation layer 900 is formed between plurality of pillars 700 and is substantially planar to the surface of silicon carbide substrate 100 of FIG. 21. FIG. 22 is not drawn to scale since thickness of remaining silicon carbide substrate 2220 is in the range of 300-400 micrometers, while the portion of silicon carbide substrate 2200 is in the range of 20-150 micrometers, depending on the thickness of epitaxial layer 1100 that is grown to form the IGBT. As mentioned previously, typically more than one IGBT is formed in silicon carbide substrate 100.

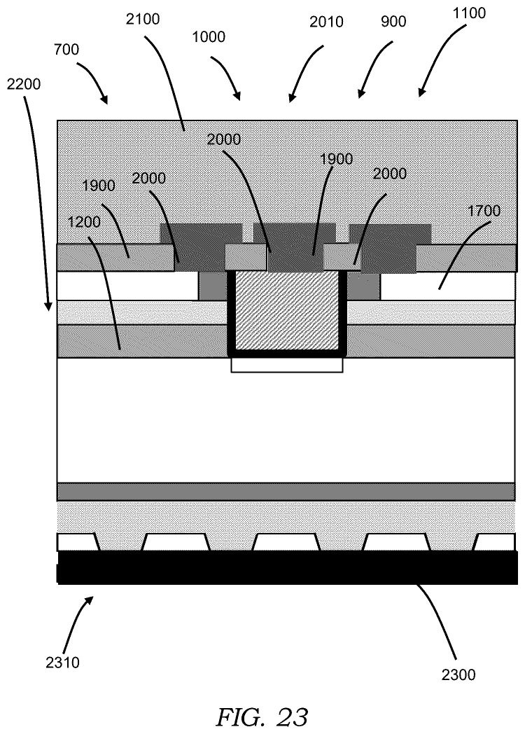

FIG. 23 is an illustration of a back side metal 2300 deposited in accordance with an example embodiment. In the example embodiment, back side metal 2300 is deposited on back surface 2310 of silicon carbide substrate 2200 with IGBT 2010 attached to carrier wafer 2100. After the exfoliation process, the exposed surface of silicon carbide substrate 2200 with IGBT 2010 attached to carrier wafer 2100 is polished to remove any remnants of plurality of pillars 700 of FIG. 7 and exfoliation layer 900 of FIG. 9. The cleaned and polished surface of silicon carbide substrate 2200 with IGBT 2010 attached to carrier wafer 2100 is coated with back side metal 2300 to form the collector electrode of the BJT of IGBT 2010. Since the thickness of merge layer 1000 of comprising the P+ injection layer can be controlled very precisely by using planarization techniques, the collector electrode of the BJT of IGBT 2010 can attain better electrical performance with higher reliability.

Back side metal 2300 is deposited using evaporation, sputtering and other methods of metal deposition. Metals such as nickel, or combination of metals such as Ti/Ni/Au (Titanium/Nickel/Gold) may be used along with annealing to reduce contact resistance to the surface of silicon carbide substrate 2200. In one embodiment, laser annealing may be used to reduce contact resistance of back side metal 2300.

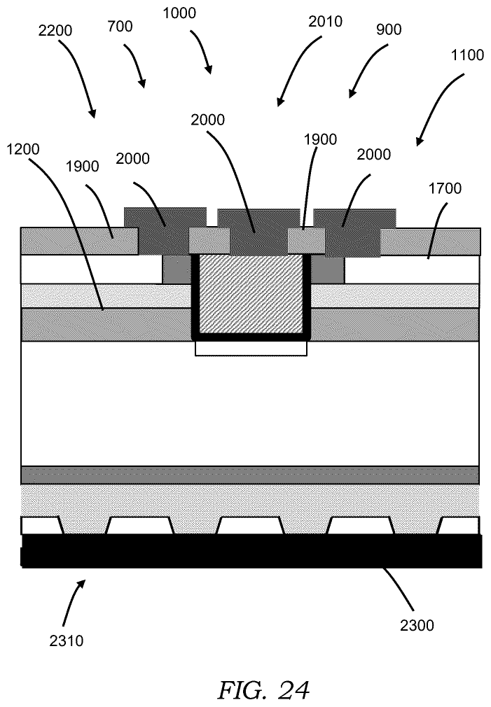

FIG. 24 is an illustration of silicon carbide substrate 2200 with IGBT 2010 after being separated from carrier wafer 2100 in accordance with an example embodiment.

It should be noted that although a single IGBT is shown fabricated on silicon carbide substrate 2200 in the example embodiment, other IGBTs will be formed simultaneously in silicon carbide substrate 2200. Typically, silicon carbide substrate 2200 can be used to form hundreds and thousands of IGBTs simultaneously, depending on the size of initial silicon carbide substrate 100 of FIG. 1. In one embodiment, the IGBTs formed in silicon carbide substrate 2200 will be diced and packaged.

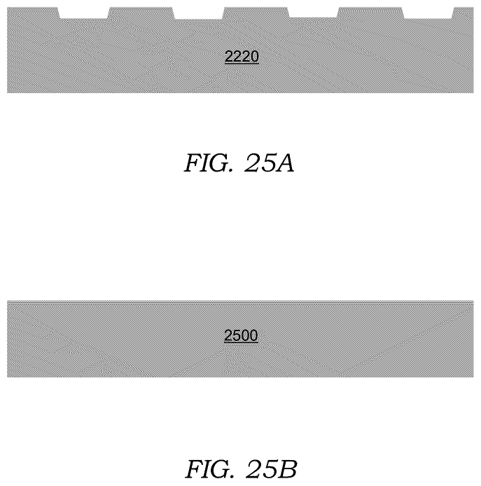

FIG. 25A is an illustration of silicon carbide substrate 2220 after exfoliation in accordance with an example embodiment. As previously disclosed, silicon carbide substrate 2220 is the major portion of silicon carbide substrate 100 of FIG. 21 after the exfoliation process. Silicon carbide substrate 2220 is reclaimed by re-polishing the surface exposed to fracture plane 2210 of FIG. 22 such that a polished surface is produced that can be used in the formation of semiconductor devices.

In one embodiment, the polishing of the surface of silicon carbide substrate 2220 of FIG. 22 is performed using CMP (chemical mechanical planarization), electrochemical polishing among other methods.

FIG. 25B is an illustration of a reclaimed silicon carbide substrate 2500 in accordance with an example embodiment. Reclaimed silicon carbide substrate 2500 is produced by the polishing of the surface of silicon carbide substrate 2220 of FIG. 22 such that it can be successively re-used for formation of semiconductor devices such as IGBTs.

By the successive application of the current invention as described by the example embodiment, the same original silicon carbide substrate 100 of FIG. 21 can be used for fabrication of silicon carbide semiconductor devices multiple times leading to significant reduction in the cost of fabrication of silicon carbide semiconductor devices. Reclaimed silicon carbide substrate 2500 can be used for successive formation of semiconductor devices using the same silicon carbide substrate 100 of FIG. 21 but with a portion removed by each subsequent exfoliation process.

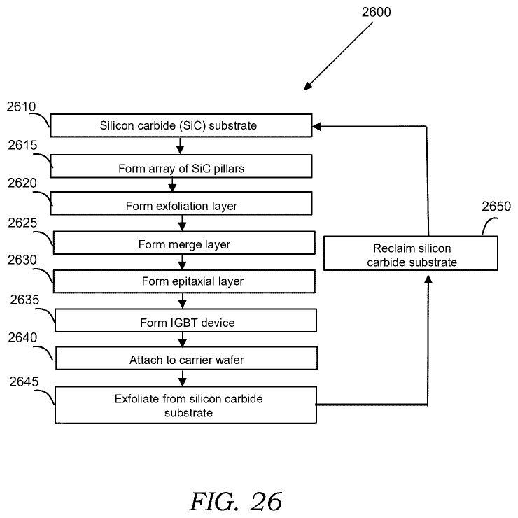

FIG. 26 is an illustration showing a block diagram 2600 of the formation of an IGBT in accordance with an example embodiment. Block diagram 2600 shows the major fabrication steps in the formation of an IGBT and re-use of the silicon carbide substrate in accordance with an example embodiment. The order of the blocks in block diagram 2600 in FIG. 26 is for illustrative purposes only and does not imply an order or show all the specific steps in the implementation of the invention as are known by one skilled in the art.

In block diagram 2600, block 2610 illustrates the silicon carbide substrate used to form the IGBT in an example embodiment. In block 2615, a plurality of pillars are formed in silicon carbide substrate and an exfoliation layer is formed between the plurality of pillars as shown in block 2620. Block 2625 shows the formation of a merge layer formed by lateral epitaxial overgrowth that has low concentration of defects such as basal plane dislocations. Block 2630 shows the epitaxial layer grown above the merge layer that also has a high quality (meaning low concentration of defects) and is suitable for formation of high voltage devices such as IGBTs. The epitaxial layer shown in block 2630 may comprise one or more layers that are grown by epitaxy. Block 2635 shows the formation of an IGBT using the epitaxial layer shown in block 2630. The details of formation of an IGBT are disclosed in detail herein above. After the IGBT is formed, the substrate is attached to a carrier wafer, as shown in block 2640. Block 2645 shows the exfoliation of the major portion of the silicon carbide substrate after formation of the IGBT, which is then reclaimed and reused multiple times, as shown in block 2650.

While the present invention has been described with reference to certain preferred embodiments or methods, it is to be understood that the present invention is not limited to such specific embodiments or methods. Rather, it is the inventor's contention that the invention be understood and construed in its broadest meaning as reflected by the following claims. Thus, these claims are to be understood as incorporating not only the preferred methods described herein but all those other and further alterations and modifications as would be apparent to those of ordinary skilled in the art.

The descriptions disclosed herein below will call out components, materials, inputs, or outputs from FIGS. 1-26.

In one embodiment, a method of forming a plurality of IGBTs 2010 (insulated gate bipolar transistors) and separating the plurality of IGBTs from a SiC (silicon carbide) substrate that is reuseable two or more times comprises a N+ silicon carbide (SiC) substrate 100, a merge layer 1000 is grown overlying the N+ Substrate wherein a surface of merge layer 1000 is P+ and the merge layer 1000 provides a surface overlying SiC substrate 100; and at least one epitaxial layer 1100 grown overlying the P+ surface of merge layer 1000 wherein the plurality of IGBTs 2010 are formed in or overlying the at least one epitaxial layer 1100 and wherein an exfoliation process is configured to separate the N+ silicon carbide substrate 100 from the at least one epitaxial layer 1100 along a plane at or underlying merge layer 1000 such that silicon carbide substrate 100 can be reused for subsequent device manufacture.

In one embodiment, the method comprises silicon carbide substrate 100 is 4H SiC.

In one embodiment, the method further includes growing epitaxial layer 200 overlying the SiC substrate 100 wherein epitaxial layer 200 underlies merge layer 1000.

In one embodiment, the method further includes forming a plurality of pillars 700 in epitaxial layer 200 by etching a plurality of trenches in epitaxial layer 200.

In one embodiment, the method wherein plurality of pillars 700 are within a range of 500 nanometers to 5000 nanometers in height.

In one embodiment, the method wherein a spacing of each pillar to an adjacent pillar of plurality of pillars 700 is in a range of (500-5000) nm.

In one embodiment, the method further includes forming an exfoliation layer 900 in the plurality of trenches. The exfoliation layer 900 has a height less than a height of each pillar of the plurality of pillars 700.

In one embodiment, the method further including growing epitaxial layer 200 by epitaxial vertical overgrowth and wherein epitaxial layer 200 is p-type and doped P+.

In one embodiment, the method wherein epitaxial layer 200 is formed by implantation and wherein epitaxial layer 200 is p-type and doped P+.

In one embodiment, the method wherein each pillar of the plurality of pillars 700 has a top surface and wherein the top surface of each pillar is minimized to reduce propagation of defects from SiC substrate 100 to epitaxial layer 1110 or epitaxial layer 1120.

In one embodiment, the method wherein merge layer 1000 is grown by epitaxial lateral overgrowth and wherein the merge layer 1000 overlies plurality of pillars 700 and exfoliation layer 900.

In one embodiment, the method wherein the top surface of each pillar of plurality of pillars 700 comprise a shape of a triangle or a hexagon.

In one embodiment, the method further including heating the exfoliation layer 900 by at least one laser wherein exfoliation layer 900 comprises carbon or tantalum carbide, wherein heating exfoliation layer 900 supports separation of SiC substrate 100 from merger layer 1000 and at least one epitaxial layer 1110, and wherein the exfoliation process occurs along a plane of exfoliation layer 900 or plurality of pillars 700.

In one embodiment, the method wherein the SiC substrate 100, merge layer 1000, and epitaxial layer 1110 are single crystal.

In one embodiment, the method further including preparing a back surface 2310 of plurality of IGBTs 2010 after the exfoliation process, depositing a back side metal 2300 on the prepared back surface 2310 of plurality of IGBTs 2010, preparing a surface of SiC substrate 2220 for further wafer processing after the exfoliation process to form the SiC substrate 2500, and reusing the SiC substrate 2500 to manufacture a plurality of devices.

In one embodiment, a method of forming a plurality of IGBTs 2010 (insulated gate bipolar transistors) and separating the plurality of IGBTs from a SiC (silicon carbide) substrate that is reuseable two or more times comprises providing N+ silicon carbide (SiC) substrate 100, growing an epitaxial layer 200 overlying SiC substrate 100, etching a plurality of trenches in epitaxial layer 200 wherein the plurality of trenches forms a plurality of pillars 700, forming an exfoliation layer 900 in the plurality of trenches, growing a merge layer 1000 overlying plurality of pillars 700 wherein the merge layer is grown by epitaxial lateral overgrowth to bridge the plurality of trenches to form a merge layer surface that overlies a surface of SiC substrate 100, and growing at least one epitaxial layer 1110 overlying merge layer 1000. Plurality of IGBTs 2010 are formed in or overlying at least one epitaxial layer 1110. An exfoliation process is configured to separate SiC substrate 100 along a plane of exfoliation layer 900 or plurality of pillars 700. SiC substrate 100 is prepared after separation for reusing the SiC substrate for a manufacture of other devices. Preparation of SiC substrate 100 can comprise removal of material by chemical mechanical planarization.

In one embodiment, epitaxial layer 200 is grown by epitaxial vertical overgrowth.

In one embodiment, epitaxial layer 200 is formed by implantation.

In one embodiment, exfoliation layer 900 comprises carbon or tantalum carbide. One or more lasers are used to heat exfoliation layer 900 to support separation of SiC substrate 100 from plurality of IGBTs 2010.

In one embodiment, a carrier wafer 2100 is coupled to plurality of IGBTs to support handling and separation of SiC substrate 100 from plurality of IGBTs 2010.

In one embodiment, a method of forming a plurality of IGBTs (insulated gate bipolar transistors) 2010 comprising providing a SiC substrate 100. Forming a first epitaxial layer 200 overlying the SiC substrate 100 wherein first epitaxial layer 200 is doped an opposite type from SiC substrate 100. First epitaxial layer 200 can be formed by epitaxial vertical overgrowth or by implantation. Etching a plurality of trenches in first epitaxial layer 200 to form a plurality of pillars 700. Forming an exfoliation layer 900 in the plurality of trenches such that exfoliation layer 900 is between each pillar of the plurality of pillars 700. In one embodiment, a height 710 of the exfoliation layer 900 is below a top surface of each pillar of the plurality of pillars 700. Exfoliation layer comprises carbon or tantalum carbide. Growing a merge layer 1000 overlying the plurality of pillars 700 by epitaxial lateral overgrowth. Merge layer 1000 bridges over the plurality of trenches to couple to each pillar of plurality of pillars 700 to form a contiguous surface. In one embodiment, merge layer 1000 forms a surface overlying SiC substrate 100. Growing at least one epitaxial layer 1110 by epitaxial vertical overgrowth. Forming the plurality of IGBTs 2010 in or overlying the at least one epitaxial layer 1110. Coupling a wafer carrier 2100 to plurality of IGBTs 2010. Applying at least one laser to exfoliation layer 900 that creates a thermal shock to stress or fracture the plurality of pillars 700. Separating plurality of IGBTs 2010 from SiC substrate 100. Preparing a surface of separated SiC substrate 100 for wafer processing reuse to form other devices.

1. A method of forming a plurality of IGBTs (insulated gate bipolar transistors) and separating the plurality of IGBTs from a SiC (Silicon Carbide) substrate that is reuseable two or more times comprising:
forming a layer overlying the SiC substrate wherein the layer comprises:
a plurality of pillars formed in a first epitaxial layer of a first type overlying the SiC substrate;
an exfoliation layer adjacent to the plurality of pillars; and
a merge layer comprising a second epitaxial layer of the first type grown by epitaxial lateral overgrowth overlying the exfoliation layer and the plurality of pillars;
growing at least one epitaxial layer of a second type overlying a surface of the merge layer wherein the plurality of IGBTs are formed in or overlying the at least one epitaxial layer; and
heating the exfoliation layer to support separation of the plurality of IGBTs from the SiC substrate.

2. The method of claim 1 wherein the silicon carbide substrate is 4H SiC and wherein the silicon carbide substrate is of the second type.

3. The method of claim 1 wherein a plurality of trenches are etched in the first epitaxial layer of the layer to form the plurality of pillars.

4. The method of claim 1 wherein the exfoliation layer comprises carbon or tantalum carbide.

5. The method of claim 1 wherein the merge layer is a barrier to a propagation of crystal defects to the at least one epitaxial layer from the SiC substrate.

6. The method of claim 1 wherein a height of the exfoliation layer is less than a height of each pillar of the plurality of pillars.

7. The method of claim 1 wherein the merge layer is configured to grow from sidewalls of each pillar of the plurality of pillars such that the epitaxial lateral overgrowth merges between adjacent pillars of the plurality of pillars.

8. The method of claim 1 4 wherein the first epitaxial layer of the layer and the at least one epitaxial layer is grown by epitaxial vertical overgrowth.

9. The method of claim 1 wherein the first epitaxial layer of the layer is formed by implantation.

10. The method of claim 1 4 wherein each pillar of the plurality of pillars has a top surface and wherein the top surface of each pillar of the plurality of pillars is minimized to reduce propagation of defects from the SiC substrate.

11. The method of claim 1 wherein the first epitaxial layer of the layer is grown in an epitaxial reactor.

12. The method of claim 1 wherein the exfoliation layer is heated by one or more lasers and wherein the heated exfoliation layer produces a thermal shock that fractures or weakens the plurality of pillars to support separation.

13. The method of claim 1 wherein the at least one epitaxial layer comprises:
a third epitaxial layer of the second type overlying the merge layer;
a fourth epitaxial layer of the second type overlying the third epitaxial layer wherein the second type doping is greater in the third epitaxial layer than the fourth epitaxial layer;
a current spreading layer of the second type in the fourth epitaxial layer;
a body implant layer of the first type in the fourth epitaxial layer wherein the body implant layer overlies the current spreading layer;
and wherein each IGBT of the plurality of IGBTs comprises:
a trench etched through body implant layer and a portion of current spreading layer;
a gate oxide layer on the walls of the trench;
a gate electrode layer in the trench and coupled to the gate oxide layer;
a source region of the second type in the body implant layer wherein the source region is adjacent to the gate oxide layer;
an implant layer of the first type in the body implant layer wherein the implant layer is adjacent to the source region;
a first electrode coupled to the source region and the implant layer; and
a second electrode coupled to the merge layer.

14. The method of claim 1 further including:
preparing a back surface of the plurality of IGBTs after an exfoliation process;
depositing a back side metal on the prepared back surface of the plurality of IGBTs wherein the prepared back surface comprises a portion of the layer;
preparing a surface of the separated SiC substrate to support further wafer processing wherein a remaining portion of the layer is removed from the separated SiC substrate; and
reusing the prepared SiC substrate.

15. The method of claim 14 wherein a separation of the plurality of IGBTs from the SiC substrate is along a plane of the layer and wherein a thickness of the portion of the layer on the plurality of IGBTs after separation is controlled by planarization techniques for improved performance.

16. A method of forming a plurality of IGBTs (insulated gate bipolar transistors) and separating the plurality of IGBTs from a SiC (Silicon Carbide) substrate that is reuseable two or more times comprising:
growing an epitaxial layer of a first type overlying the SiC substrate of a second type wherein the epitaxial layer is grown by epitaxial vertical overgrowth;
etching a plurality of trenches in the epitaxial layer wherein the plurality of trenches are patterned to form a plurality of pillars;
forming an exfoliation layer in the plurality of trenches;
growing a merge layer overlying the plurality of pillars and the exfoliation layer wherein the merge layer is a second epitaxial layer of a first type grown by epitaxial lateral overgrowth and wherein the merge layer has a surface that overlies a surface of the silicon carbide substrate;
growing at least one epitaxial layer overlying the merge layer wherein the plurality of IGBTs are formed in or overlying the at least one epitaxial layer;
using one or more lasers to heat the exfoliation layer to weaken or fracture the plurality of pillars wherein the SiC substrate is separated from the plurality of IGBTs along a plane of the exfoliation layer; and
preparing a surface of the separated SiC substrate for reuse.

17. The method of claim 16 wherein the exfoliation layer comprises carbon, tantalum carbide, or a polymer converted to carbon by pyrolysis and wherein a height of the exfoliation layer is less than a height of each pillar of the plurality of pillars.

18. The method of claim 16 wherein the merge layer is a barrier to a propagation of crystal defects to the at least one epitaxial layer from the SiC substrate.

19. The method of claim 16 wherein remaining portions of the plurality of pillars are removed from the surface of the separated SiC substrate, wherein at least a portion of the merge layer and at least a portion of the plurality of pillars remains on the plurality of IGBTs after separation, and wherein a thickness of the portion of the merge layer and the at least a portion of the plurality of pillars remaining on the plurality of IGBTs is controlled by planarization techniques to for improved performance.

20. The method of claim 16 further including coupling a carrier wafer to the plurality of IGBTs wherein a torque or pulling force can be applied to the plurality of IGBTs or the SiC substrate to support handling and separation of the SiC substrate from the plurality of IGBTs.

21. A method of forming a plurality of IGBTs (insulated gate bipolar transistors) and separating the plurality of IGBTs from a SiC (Silicon Carbide) substrate that is reuseable two or more times comprising:
growing an epitaxial layer overlying the SiC substrate wherein the epitaxial layer is grown by epitaxial vertical overgrowth;
etching a plurality of trenches in at least the epitaxial layer wherein the plurality of trenches are patterned to form a plurality of pillars;
forming a layer of carbon or tantalum carbide in the plurality of trenches;
growing a merge layer overlying the plurality of pillars and the layer of carbon or tantalum carbide wherein the merge layer is a second epitaxial layer grown by epitaxial lateral overgrowth;
growing at least one epitaxial layer overlying the merge layer wherein the plurality of IGBTs are formed in or overlying the at least one epitaxial layer;
coupling a carrier wafer to the plurality of IGBTs;
using one or more lasers to heat the layer of carbon or tantalum carbide to weaken or fracture the plurality of pillars;
separating the SiC substrate from the plurality of IGBTs using a torque or pulling force on the wafer carrier or SiC substrate wherein the separation occurs along a plane of the plurality of pillars; and
removing remaining plurality of pillars from the separated SiC substrate such that the separated SiC substrate is reuseable for wafer processing.
